(19) United States
(12) Patent Application Publication
(10) Pub. No.: US 2026/0155807 A1
(43) Pub. Date: Jun. 4, 2026

(54) MULTIPORT BROADBAND MONOLITHIC PHASE-CHANGE RADIO FREQUENCY SWITCH

(71) Applicant: Dell Products L.P., Round Rock, TX (US)

(72) Inventors: Tejinder Singh, Manotick (CA); Navjot Kaur Khaira, Manotick (CA)

(21) Appl. No.: 18/968,887

(22) Filed: Dec. 4, 2024

(51) Int. Cl. H03K 3/01; H01P 1/15; H03K 17/56; H05B 3/26; H10N 70/00; H10N 70/20

(52) U.S. Cl. CPC H03K 3/01; H01P 1/15; H03K 17/56; H05B 3/26; H10N 70/011; H10N 70/231; H10N 70/8413; H10N 70/8828

(57) ABSTRACT

The technology described herein is directed towards phase change material-based (e.g., chalcogenide) radio frequency switch device. The switch device has phase change material junctions between selectable ports and a common port, in which the phase change material junctions are controlled to be in either conductive or nonconductive states, thereby respectively coupling or decoupling each selectable port to (or from) the common port. A controller can selectively pulse the respective junctions of a multiport switch device to independently determine their respective conductive or nonconductive states. In one implementation, the switch design is symmetrical so that any one of the multiple selectable ports has very similar performance characteristics to that of any other selectable port. The phase change alloy switch device described herein provides high switching speeds, low insertion loss, good isolation and is relatively straightforward to fabricate.

### BACKGROUND

Radio frequency (RF) switches control the routing of RF signals in communication systems, and are used for tasks like antenna selection and signal path switching. Common types of RF switches include PIN diodes, FET (field effect transistor)/GaN (Gallium Nitride) switches, and MEMS (micro-electromechanical systems) switches, each with unique characteristics in terms of speed, power consumption, and performance.

RF switches are used in devices such as mobile phones, base stations, and phased array antennas for tasks like signal routing, antenna switching, and phase shifting. Important factors for RF switches include insertion loss (signal loss through the switch), isolation (preventing signal leakage between paths), and switching speed (how quickly the switch changes states). Existing RF switches often suffer from at least one of high insertion loss, poor isolation, and/or complex fabrication processes, limiting their applicability in space-constrained high-performance scenarios.

### BRIEF DESCRIPTION OF THE DRAWINGS

The technology described herein is illustrated by way of example and not limited to the accompanying figures in which like reference numerals indicate similar elements and in which:

FIG. 1 is an exploded three-dimensional (3D) view representation of an example multi-layer structure of a model of a multiport broadband radio frequency (RF) switch device in which switching is achieved by using phase change alloy (chalcogenide) material junctions, in accordance with various embodiments and implementations of the subject disclosure.

FIG. 2A shows a two-dimensional (2D) device cross-section view representation of the example switch device of FIG. 1, in accordance with various embodiments and implementations of the subject disclosure.

FIG. 2B shows an example of reversible switching of phase change material between an amorphous (high resistance) and crystalline (low resistance) states using a first electrical pulse for one state change and a second electrical pulse for a state change reversal, in accordance with various aspects and implementations of the subject disclosure.

FIGS. 3A and 3B show how the example switch device can be controlled to selectively couple a common RF port to a selectable RF port, in accordance with various aspects and implementations of the subject disclosure.

FIG. 4 is an exploded 3D view representation of an example switch device showing the port configuration, in which switching is achieved by using chalcogenide material junctions, in accordance with various embodiments and implementations of the subject disclosure.

FIG. 5 is a top view representation of an example switch device showing the port configuration, in which switching is achieved by using chalcogenide material junctions, in accordance with various embodiments and implementations of the subject disclosure.

FIGS. 6A, 6B, 6C, 7A, 7B and 7C show example manufacturing steps to form an example switch device, in accordance with various embodiments and implementations of the subject disclosure.

FIG. 8 shows example switch operational states and junction design parameters used in the example switch device, in accordance with various embodiments and implementations of the subject disclosure.

FIG. 9 is a rendering of an example switch junction of a single port switch, in accordance with various embodiments and implementations of the subject disclosure.

FIGS. 10A, 10B, 11A, 11B, 12A, 12B, 13A, 13B, 14, 15A, 15B, 16A, 16B, 17A and 17B show results of example simulations for various switch design parameters, in accordance with various embodiments and implementations of the subject disclosure.

FIGS. 18A and 18B show performance results of an example broadband multiport RF switch, including insertion loss (FIG. 18A) and return loss and isolation (FIG. 18B), in accordance with various embodiments and implementations of the subject disclosure.

FIGS. 19 and 20 comprise a flow diagram showing example operations related to changing switch states based on changing phase change alloy material junction states, in accordance with various aspects and implementations of the subject disclosure.

### DETAILED DESCRIPTION

Various implementations and embodiments of the technology described herein are generally directed towards a highly efficient, low loss, and compact multiport radio frequency (RF) switch, such as for use in reconfigurable and adaptive networks. The multiport RF switch is based on phase change alloy technology, which can be optimized for broadband RF applications. The phase change alloy switch device described herein provides high switching speeds, low insertion loss, good isolation and is relatively straightforward to fabricate, unlike existing switch solutions. For example, MEMS switches offer low insertion loss and good isolation, but suffer from slower switching speeds and mechanical reliability issues, particularly in harsh environments. PIN diode switches provide faster switching speeds but at the cost of higher insertion losses and more complex biasing requirements, which can complicate system design and integration. GaN-based switches are known for their ability to handle high power levels and operate effectively at high frequencies; however, they typically require intricate fabrication processes and can introduce significant insertion losses, especially in broadband applications.

It should be understood that any of the examples and/or descriptions herein are non-limiting. Thus, any of the embodiments, example embodiments, concepts, structures, functionalities or examples described herein are non-limiting, and the technology may be used in various ways that provide benefits and advantages in communications and computing in general.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some practical limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

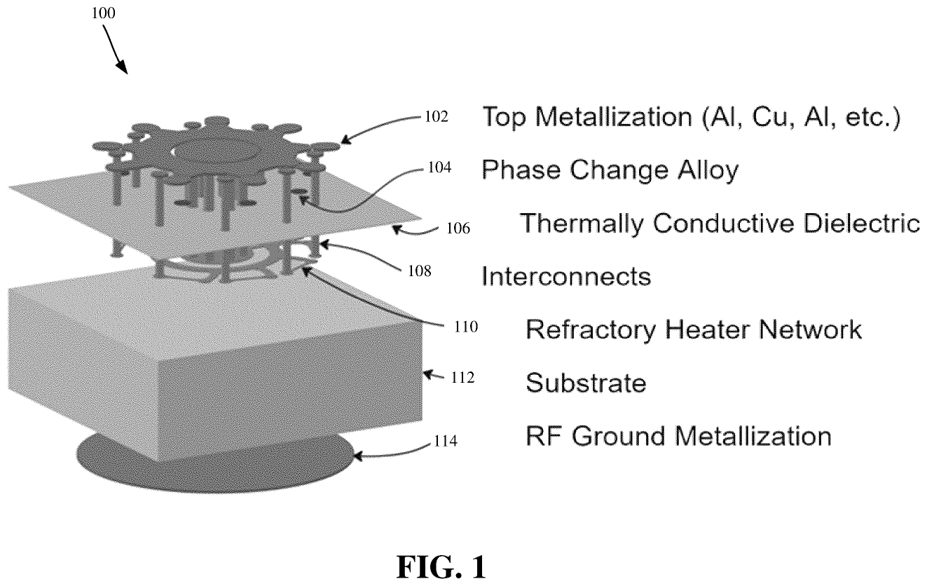

FIG. 1 shows an example (exploded view) of a multiport RF switch device 100 that utilizes phase-change alloy, offering a compact and efficient design, such as for broadband applications. As described herein, the switch device 100 includes integrated phase change (e.g., chalcogenide) material that can be controllably toggled between higher resistance and lower resistance states, enabling efficient signal routing with minimal insertion loss and high isolation.

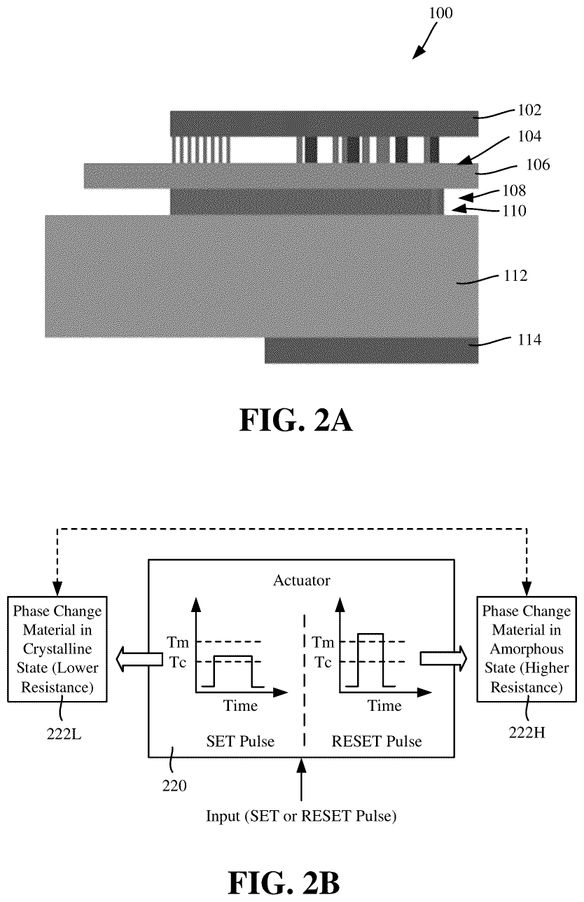

As shown in FIGS. 1 and 2A, an example embodiment of the switch 100 is constructed with a simplified material stack that includes three metallization layers and two dielectric layers, which enhances manufacturability and reduces complexity. More particularly, from the top downwards, a top metallization (e.g., Aluminum, Copper, or the like) layer 102 is above phase change alloy 104, which serve as junctions that can be individually switched from conductive to nonconductive states, and vice-versa. The phase change alloy 104 can be deposited as the per-selectable port junctions on a thermally conductive dielectric layer 106.

In general, the thermally conductive dielectric layer 106 helps manage heat dissipation effectively, ensuring reliable operation across a wide range of thermal conditions. The multiport configuration supports flexible signal routing in complex communication systems, making it particularly suitable for applications such as reconfigurable RF front-ends, adaptive antenna systems, and secure communication networks.

Interconnects 108 couple a refractory heater network 110 comprising individual heating elements to voltage pulse (Vp) contacts in the top metallization layer 102, whereby the conductive and nonconductive junction states can be controllably toggled on an individual basis. Other interconnects couple the RF signals to or from the ports.

The various layers and components are fabricated atop a substrate 112, and an RF ground metallization layer 114 is beneath the substrate 112. Note that in alternative implementations, at least some alternative interconnects can be used to place at least some of the voltage pulse contacts and/or RF contacts beneath and through the RF ground metallization layer 114.

Turning to the phase change junctions'individual phases, in one example implementation the respective ports can be switched in (coupled) or switched out (decoupled) based on the conductive or nonconductive states of the respective chalcogenide elements such as described in the examples herein. In general, with respect to heating phase change (chalcogenide) alloy material to change a junction's state from conductive (crystalline) state to nonconductive (amorphous) state and vice-versa, antimony telluride (SbTe) and germanium telluride (GeTe) are suitable phase change materials. GeSbTe can be tailored to offer more than six orders of magnitude change in material's resistivity with switching time on the order of sub-nanoseconds (ns), and thus provides more electrical contrast between the two states than SbTe, for example, (which offers up to four orders of magnitude change in material's resistance with switching time on the order of sub-picoseconds). GeSbTe also offers ultra-low resistance in crystalline state, offering better electromagnetic waves interaction and low resistive losses which are more prominent in SbTe.

Switching between the two states can be achieved by applying thermal energy such as a pulse with certain amplitude and width (duration on the order of nanoseconds (ns)) through an electrically insulated high-speed heater. Note that such phase change material holds its state as long as it is not actuated with another either crystalline or amorphous pulse, whereby the technology described herein offers energy-efficient switch reconfigurability, in that power is needed intermittently, that is, only during the reconfiguration phase when the heaters are actuated to change the state of the phase change material. Once the desired pattern is achieved, the material retains its state without the need for ongoing power.

As shown in FIG. 2B, a medium amplitude and relatively longer duration (typically on the order of nanoseconds) SET electrical pulse (e.g., represented in the left portion of the actuator) of an actuator (heating element) 220 is used for crystallization during a transition to the ON state. Energy from the SET pulse heats the material for sufficient time to crystallize the material and provides adequate time for atoms to reorganize to an orderly arrangement, thus transforming from an amorphous state to crystalline state (block 222L, or low). To change to the amorphous state, a short duration (typically less nanoseconds than for the SET pulse) and high amplitude RESET electrical pulse is used. The RESET pulse provides sufficient energy to melt the material to disorder the atoms followed by rapid quenching to freeze the atoms, thus transforming the material from the crystalline state to the amorphous state (block 222H, or high). Significantly, only a short duration pulse to a heating element is needed to switch the state of the phase change material between states at the area/portion above the corresponding heating element; significantly, the pulse transforms the material and latches the material into the state, without the need for continuous power in either state. The pulse duration and amplitude can be further optimized by tuning the ratio of GeSbTe alloy ratios.

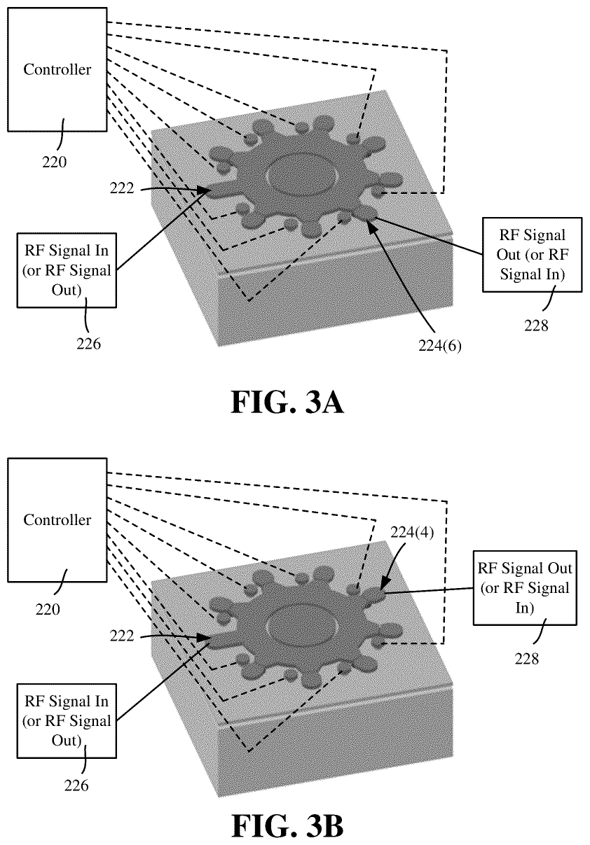

FIGS. 3A and 3B show how the example switch device 100 can be controlled by a controller 220 to selectively couple a common RF port 222 to a selectable RF port 224(6), FIG. 3A, or to a different selectable RF port 224(4), FIG. 3B. In FIG. 3A, the controller 220 pulses the phase change material alloy of the ports such that the selectable port 224(6) is conductively coupled to the common RF port 222, while the other ports are decoupled from the common RF port 222. This allows an RF signal 226 (input at the common port 222) to be obtained at the selectable port 224(6) for RF signal output 228, or vice-versa (signal input at the selectable port and output via the common port 222). At some other time, FIG. 3B shows how the controller 220 pulses the phase change material alloy of the ports such that the selectable port 224(4) is conductively coupled to the common RF port 222, while the other ports are decoupled from the common RF port 222.

The operation principle of the example switch device 100 of FIG. 1 is thus based on the many orders of magnitude resistance change that chalcogenide phase change GST alloys undergo when provided a specific heat treatment using a pulse, as described with reference to FIG. 2B. Such materials can reversibly transition between a low resistance (metallic/conductive) state to a high resistance (insulator/resistive) state. This transition occurs due to the change in crystal structure of the alloy, which changes from amorphous to crystalline. In order to control the states of the material, the heater network 110 (FIG. 1) has distributed heating elements placed below the phase change material (chalcogenide material) junctions. Hence, which port or ports are coupled to a common port can be achieved at a high speed, which provides ultrafast reconfigurable operation of the switch device.

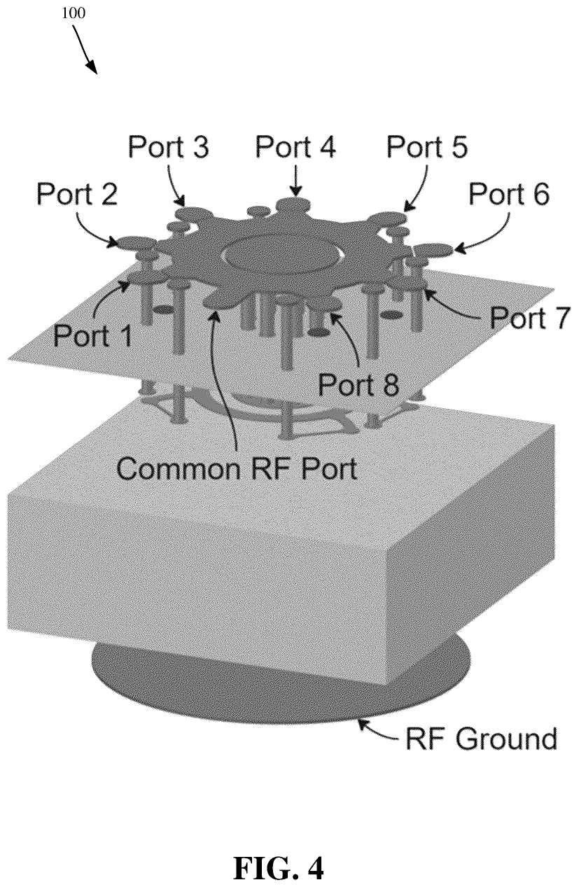

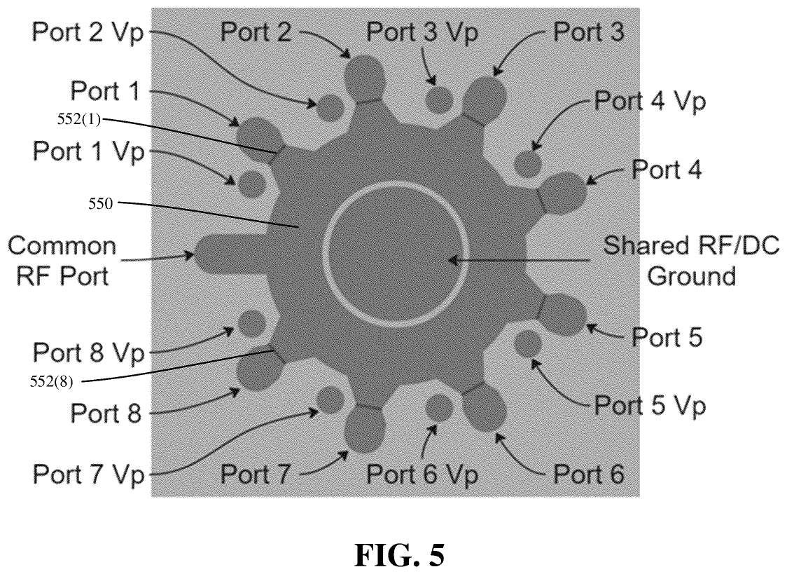

FIGS. 4 and 5 show the port configuration of an example eight port (plus one common RF port) switch device 100, which is thus a single-pole, eight-throw (SP8T) switch. Thus, there can be eight different RF signal inputs from selectable Port 1-Port 8 that goes to one output port common (the common RF port), or one common input (the common RF port) that can go to any of the eight selectable ports as output.

As shown in FIG. 5, a conductor 550 is coupled to the common RF port. Whether a selectable port (Port 1-Port 8) is coupled to the conductor 550 depends on the conductive or nonconductive state of its phase change alloy junction, shown as thin dark lines between the ports and the conductor 550. Two such junctions, 552(1) for Port 1, and 552(8) for port 8, are labeled in FIG. 5; (the other junctions are not labeled for purposes of clarity).

In this example implementation, the design of the switch ports is purely symmetrical, whereby there is no significant performance difference between any ports, as they share the same circular ring. Note that other designs are feasible, and are not limited to symmetrical switch designs, nor to a single-pole, eight-throw switch; e.g., the technology described herein can be used for a SPnT switch, where n is any practical number.

As identified in FIG. 5, a middle disk serves as a shared RF/DC ground in the upper metallization layer 102 (FIG. 1). Also identified in FIG. 5 are the voltage pulse contacts, Port 1 Vp-Port 8 Vp, by which voltage pulses can be applied to change the respective conductive or nonconductive states of the respective junctions, thereby controllably coupling the common port to any controllably selected port.

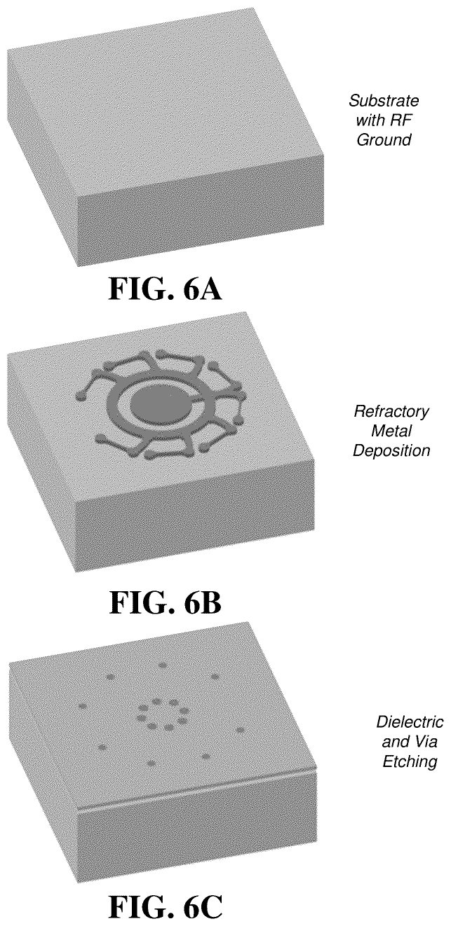

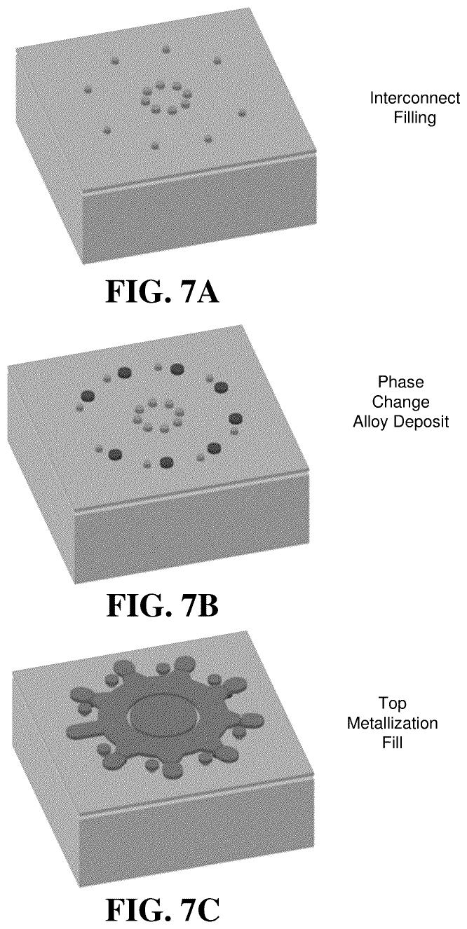

FIG. 6A-7C show how the switch can be manufactured in steps, from the bottom up, beginning with FIG. 6A which shows the substrate with RF ground (not visible) at the bottom. A second step shown in FIG. 6B adds a refractory heater layer by metal deposition, e.g., a tungsten layer that acts as the heating element layer. FIG. 6C shows the dielectric with via etching providing openings for filling with the interconnects (FIG. 7A). The phase change material is next deposited as shown in FIG. 7B. The top metallization layer is then filled in (FIG. 7C).

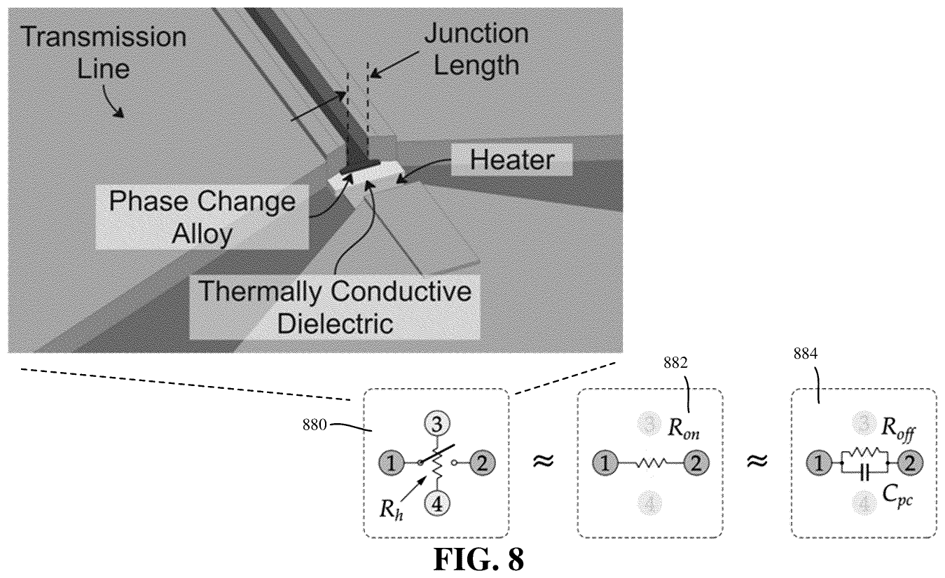

FIG. 8 shows switch operational states and junction design parameters; the switch model (block 880) depicts the configuration, including the heater resistance Rₕ, which controls the phase transition. In the ON state (block 882), the switch acts as a simple low-resistance path Rₒₙ, allowing RF signal transmission. In the OFF state (block 884), the switch behaves as a high-resistance path R_{off} with additional parasitic capacitance C_{pc}, effectively blocking the RF signal.

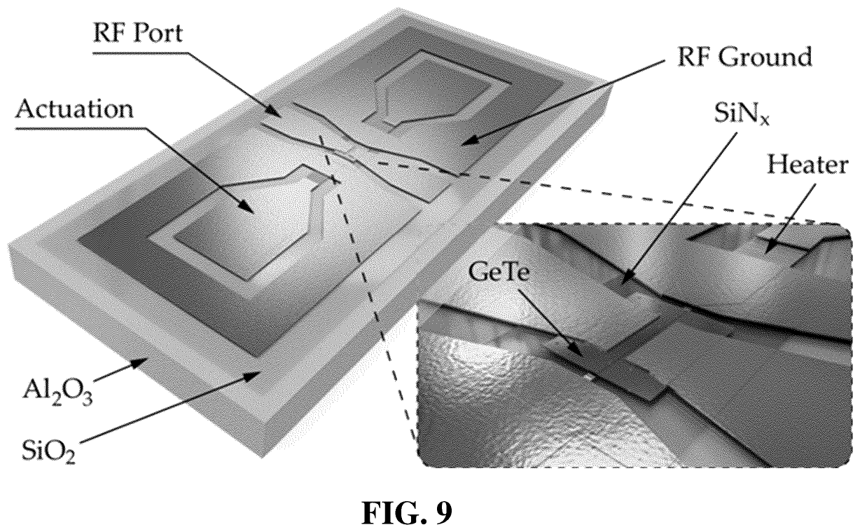

FIGS. 8 and 9 also show a single port switch with an area for optimization, in which the junction of the switch and the GeTe material is highlighted. A parameter for the junction is how much gap to create between the two metal lines. In particular, if the two metals are very close to each other, along with the heater which is also a metal metallic element, parasitic capacitance is created with respect to RF signals, creating unwanted coupling that reduces isolation performance. However, keeping the metals too far away increases loss because the phase material is resistive. There is thus a balance in determining the design of the junction, including channel width, channel length, taper length, heater width and metal thickness; (e.g., the heater needs to be as narrow as possible to reduce the parasitic capacitance, but without degrading the performance).

Various designs were simulated with design iteration over DC to 22 gigahertz to demonstrate the potential of designed RF switches and their broadband performances. Parameters include thin film metal thickness in microns; varying the metal film thickness from 0.4 to 0.8 microns has a reflection of −28 dB to −32 dB, which should be as low as possible.

With respect to simulation and optimization, return loss measures how much of the input signal is reflected back towards the source due to impedance mismatches in the RF switch. Insertion loss refers to the loss of signal power that occurs when the RF signal passes through the switch, and isolation measures how well the RF switch can prevent signal leakage from one port to another when the switch is in the OFF state. The multi-port switch is designed by optimizing the design parameters such as channel width, channel length, taper length, heater width and metal thickness for better return loss, insertion loss, and isolation performance.

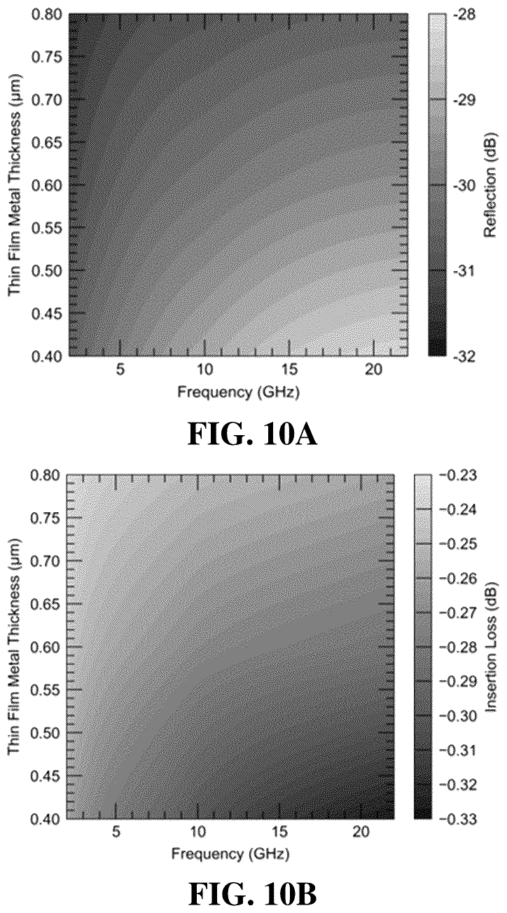

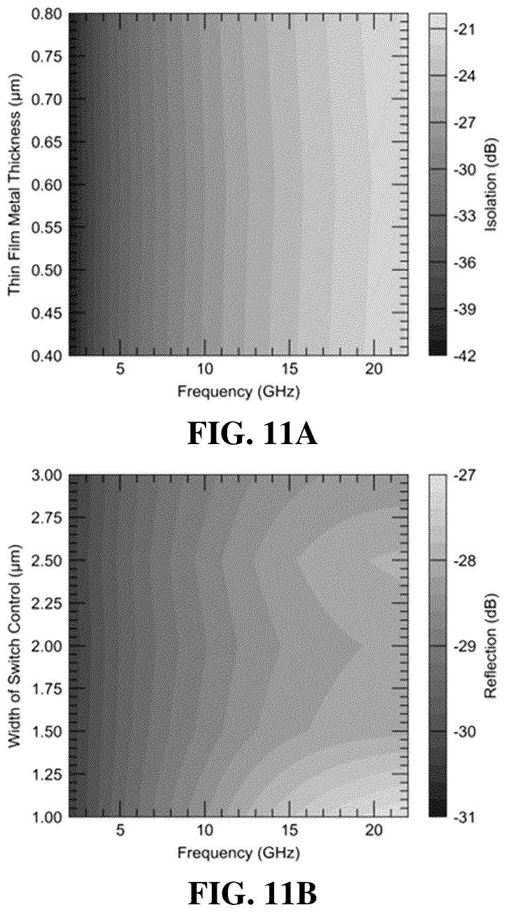

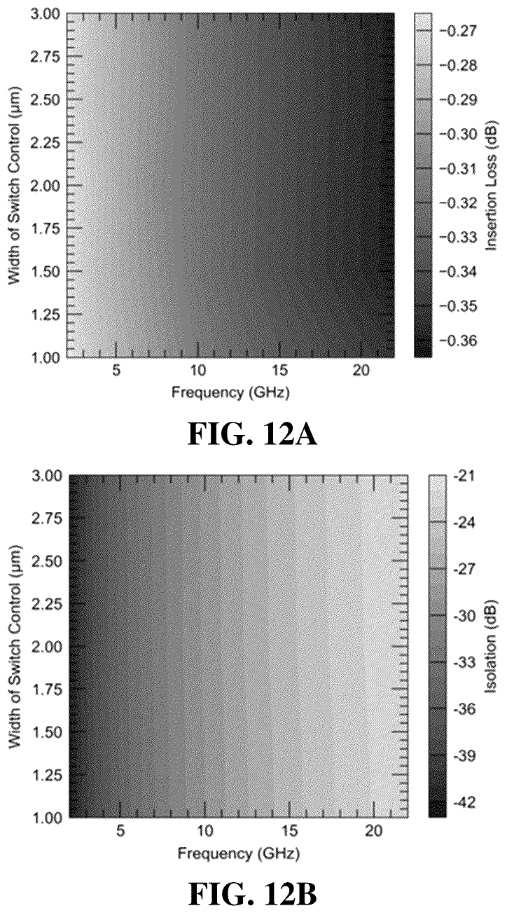

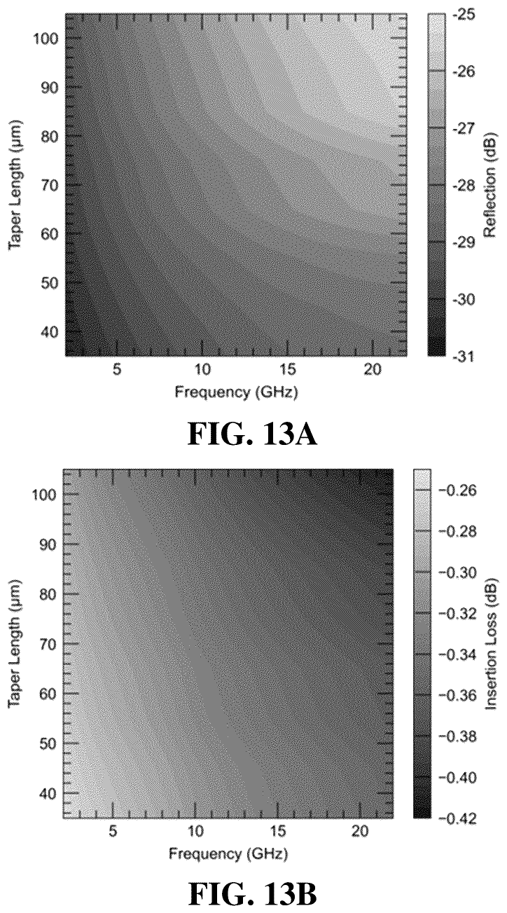

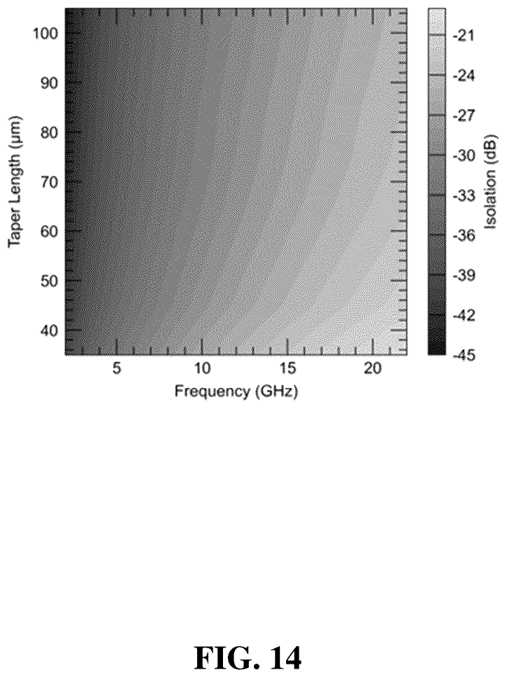

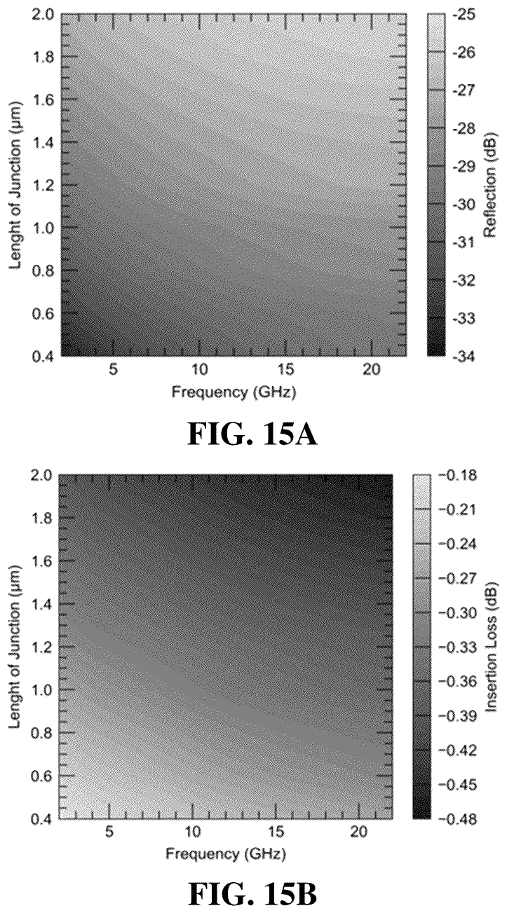

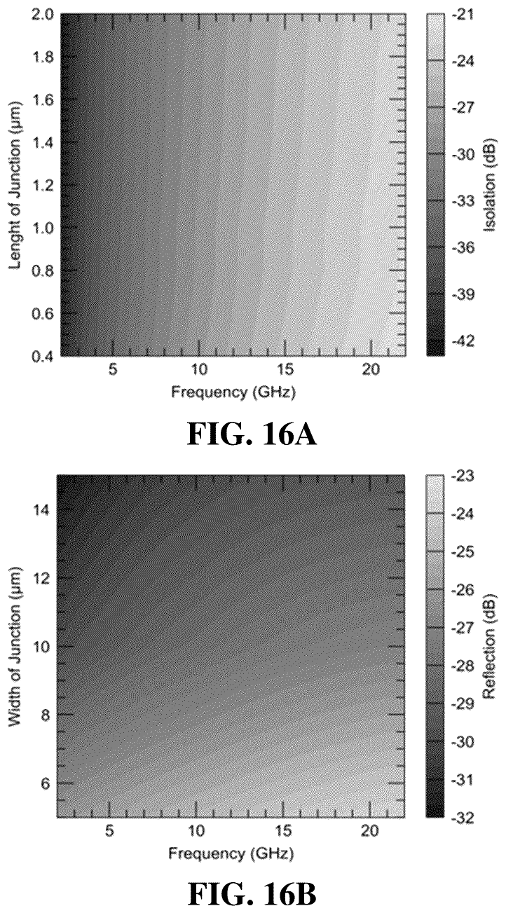

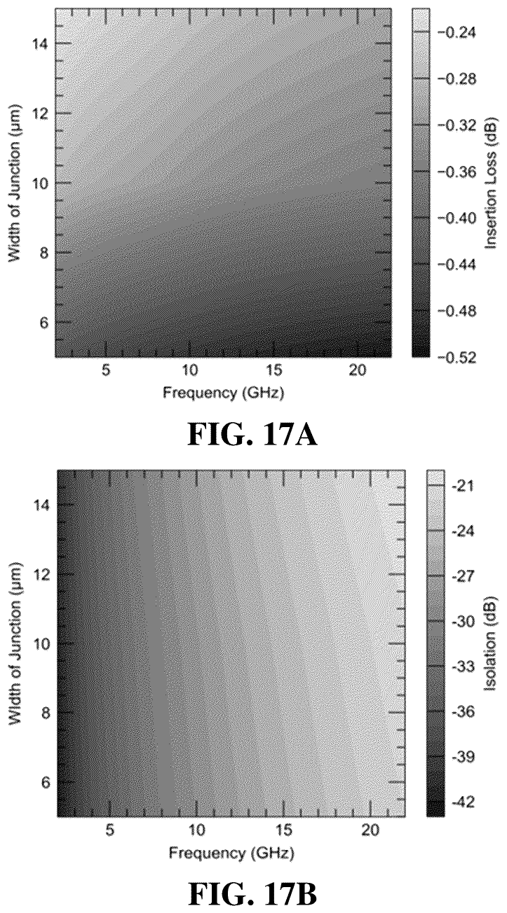

Simulations were performed in a full-field 3D electromagnetic solver. Results are shown in FIGS. 10A-17B for the variations of the different parameters over design iterations with respect to return loss, insertion loss, and isolation performance, over DC to 22 GHz to demonstrate the RF switches and their broadband performance. As can be seen, the RF switches demonstrate exceptional performance below 8 GHz.

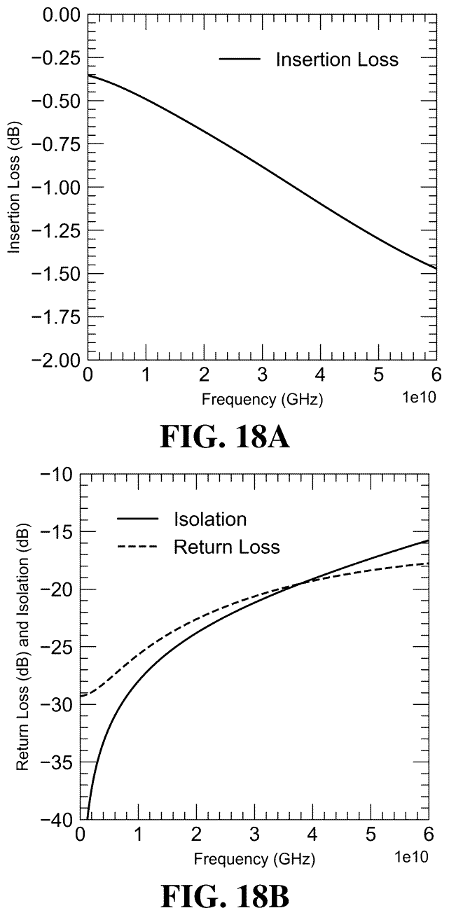

FIG. 18A graphically shows that the insertion loss of one example switch device slightly increases from −0.3 dB to −1.5 dB across 0 to 60 GHz, indicating minimal signal loss throughout the frequency range. FIG. 18B shows that return loss varies from −28 dB to −15 dB as frequency increases, demonstrating better impedance matching and reduced signal reflection at below 30 GHz frequencies. FIG. 18B shows that isolation reduces from −35 dB to −27 dB across the frequency band, which ensures effective separation of signals and minimizing interference over wideband frequencies.

One or more implementations can be embodied in a device, including a radio frequency (RF) switch including a common RF port and respective selectable RF ports, respective phase change material junctions coupled to the respective selectable ports, and a controllable heater network. The controllable heater network can include respective heating elements that transfer heat to the respective phase change material junctions, the controllable heater network being controlled to output heat via energy pulses to selectively change a first set of one or more of the respective phase change material junctions to a lower resistance state that electrically couples the common RF port to a first group of the respective selectable ports, and to selectively change a second set of the one or more of the respective phase change material junctions to a lower resistance state that electrically decouples the common RF port from a second group of the respective selectable ports.

The common RF port can include an input port for a signal, and the signal can be routed to the first group.

The common RF port can include an output port, and the first group can include a single selectable port via which an input signal at the single selectable port can be coupled to the common RF port.

The respective selectable ports can include eight selectable ports.

The respective selectable ports can be symmetrically distributed relative to the common RF port.

The respective selectable ports and the common RF port can be symmetrically distributed around a centered ground portion of the RF switch.

The ground portion can include a shared RF and direct current ground.

The device further can include a thermally conductive dielectric layer between the respective phase change material junctions and the heater network.

The RF switch can be designed for frequencies below about twenty-five gigahertz.

The phase change material junctions can include at least one of:
germanium telluride or antimony telluride.

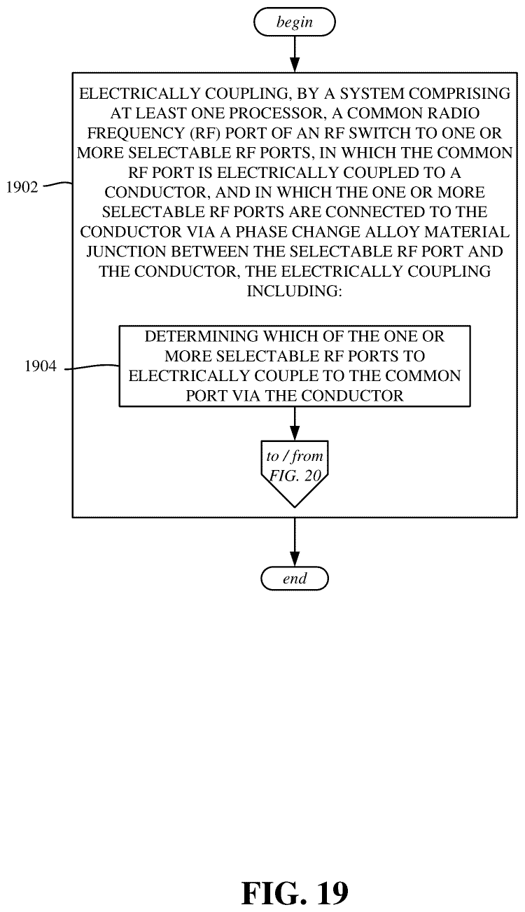

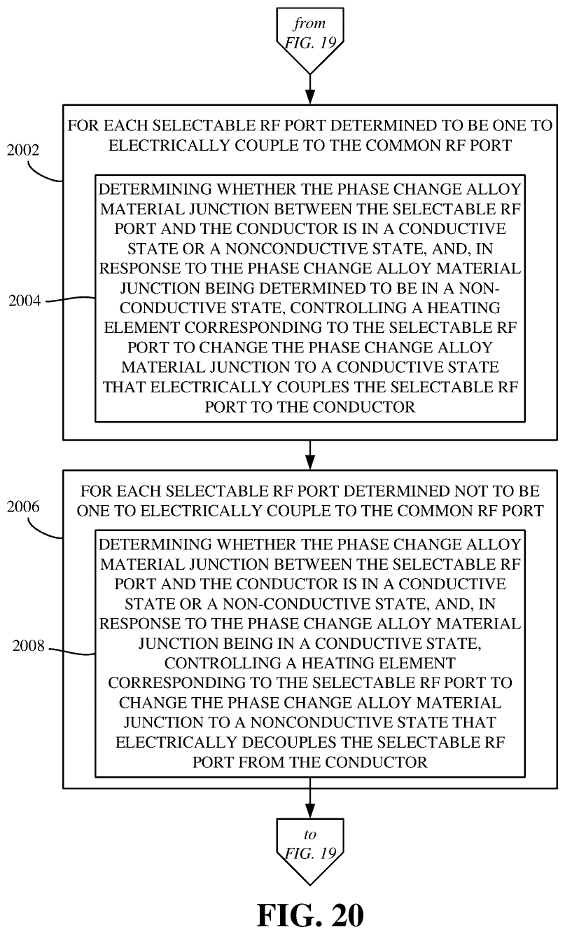

One or more example aspects, such as corresponding to example operations of a method, can be represented in FIGS. 19 and 20. Example operation 1902 of FIG. 19 represents electrically coupling, by a system including at least one processor, a common radio frequency (RF) port of an RF switch to one or more selectable RF ports, in which the common RF port can be electrically coupled to a conductor, and in which the one or more selectable RF ports can be connected to the conductor via a phase change alloy material junction between the selectable RF port and the conductor. The electrically coupling can include example operation 1904, which represents determining which of the one or more selectable RF ports to electrically couple to the common port via the conductor. The electrically coupling can include example operations 2002, 2004, 2006 and 2008 of FIG. 20. Example operation 2002 of FIG. 20 represents, for each selectable RF port determined to be one to electrically couple to the common RF port, example operation 2004, which represents determining whether the phase change alloy material junction between the selectable RF port and the conductor can be in a conductive state or a nonconductive state, and, in response to the phase change alloy material junction being determined to be in a nonconductive state, controlling a heating element corresponding to the selectable RF port to change the phase change alloy material junction to a conductive state that electrically couples the selectable RF port to the conductor. Example operation 2006 represents, for each selectable RF port determined not to be one to electrically couple to the common RF port, example operation 2008, which represents determining whether the phase change alloy material junction between the selectable RF port and the conductor can be in a conductive state or a nonconductive state, and, in response to the phase change alloy material junction being in a conductive state, controlling a heating element corresponding to the selectable RF port to change the phase change alloy material junction to a nonconductive state that electrically decouples the selectable RF port from the conductor.

The common RF port can be an input port that obtains an input signal, and the electrically coupling can include determining at least one of the one or more selectable RF ports as at least one corresponding output port usable to obtain the input signal.

The common RF port can be an output port, and further operations can include determining, by the system, a single selectable RF port of the one or more selectable RF ports to be an input port that obtains an input signal, and in which the electrically coupling couples the single selectable RF port to the common RF port.

The single selectable RF port can be a first selectable RF port determined to be a first input port, the input signal can be a first input signal, and further operations can include determining, by the system, a second selectable RF port, other than the first selectable RF port, to be a second input port that obtains a second input signal, and in which the electrically coupling couples the second input port RF port to the common RF port and decouples the first input port from the common RF port.

Controlling the heating element can include pulsing the heating element with a first voltage or a current pulse to change the phase change alloy material junction to the conductive state, or pulsing the heating element with a second voltage or current pulse to change the phase change alloy material junction to the nonconductive state.

One or more implementations can be embodied in a multiport switch. The multiport switch can include a common radio frequency (RF) port, conductive material coupled to the common RF port, and respective selectable RF ports. The multiport switch can include respective phase change alloy junctions between the conductive material and the respective selectable RF ports, and respective heating elements that can be individually controllable to determine whether the respective phase change alloy junctions can be in respective conductive states or in respective nonconductive states, in which a phase change alloy junction of the respective phase change alloy junctions, in a conductive state, electrically couples a selectable RF port of the respective selectable RF ports to the conductive material, and in which the phase change alloy junction of the respective phase change alloy junctions, in a nonconductive state, electrically decouples the selectable RF port of the respective selectable RF ports from the conductive material.

The common RF port and the respective selectable ports can be symmetrically distributed around a centered ground portion of the RF switch.

The common RF port can include an input port for a signal.

One selectable RF port of the respective selectable RF ports can be electrically coupled to the conductive material to route a signal from the one selectable RF port to the common RF port.

The multiport switch further can include a thermally conductive dielectric layer between the respective phase change alloy junctions and the respective heating elements.

As can be seen, the technology described herein facilitates an ultracompact switch device that can be monolithically integrated with other circuits and sub-systems including filters, phase-shifters, attenuators, and so on. The phase change alloy-based RF switch overcomes the limitations of other types of RF switches, and can offer a balance between performance, reliability, and ease of manufacturing in advanced RF systems.

The RF switch integrates phase change alloy enables efficient routing with reversible switching between high and low resistance states, minimizing insertion loss and enhancing isolation. The manufacturing process for the switch device needs only three metallization layers and two dielectric layers; by incorporating a thermally conductive layer, heat dissipation from high RF power can be managed, enabling stable performance over a wide surrounding temperature range.

Example applications include reconfigurable RF front-ends, adaptive antenna systems, and secure communication links. The switch can dynamically route signals to different antenna elements for beam steering, load balancing, and interference mitigation in 5G and next-gen wireless networks, enable frequency agility and multi-band operation in communication systems by switching between different signal paths or frequency bands, and/or create secure, encrypted communication links by dynamically altering the signal routing, making it harder for unauthorized interception. The switch can optimize signal routing in multi-beam satellite antennas, allowing for flexible communication paths based on satellite positioning and coverage needs, provide versatile signal routing for automated test setups, reducing the need for multiple dedicated switches and improving test efficiency, allow for seamless switching between different frequency bands or radar modes in advanced radar systems for military, automotive, or aerospace applications, and/or support dynamic reconfiguration of network paths in dense internet of things (IoT) environments, improving network reliability and performance.

What has been described above include mere examples. It is, of course, not possible to describe every conceivable combination of components, materials or the like for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
a radio frequency (RF) switch comprising a common RF port and respective selectable RF ports;
respective phase change material junctions coupled to the respective selectable ports; and
a controllable heater network comprising respective heating elements that transfer heat to the respective phase change material junctions, the controllable heater network being controlled to output heat via energy pulses to selectively change a first set of one or more of the respective phase change material junctions to a lower resistance state that electrically couples the common RF port to a first group of the respective selectable ports, and to selectively change a second set of the one or more of the respective phase change material junctions to a lower resistance state that electrically decouples the common RF port from a second group of the respective selectable ports.

2. The device of claim 1, wherein the common RF port comprises an input port for a signal, and wherein the signal is routed to the first group.

3. The device of claim 1, wherein the common RF port comprises an output port, and wherein the first group comprises a single selectable port via which an input signal at the single selectable port is coupled to the common RF port.

4. The device of claim 1, wherein the respective selectable ports comprise eight selectable ports.

5. The device of claim 1, wherein the respective selectable ports are symmetrically distributed relative to the common RF port.

6. The device of claim 1, wherein the respective selectable ports and the common RF port are symmetrically distributed around a centered ground portion of the RF switch.

7. The device of claim 1, wherein the ground portion comprises a shared RF and direct current ground.

8. The device of claim 1, further comprising a thermally conductive dielectric layer between the respective phase change material junctions and the heater network.

9. The device of claim 1, wherein the RF switch is designed for frequencies below about twenty-five gigahertz.

10. The device of claim 1, wherein the phase change material junctions comprise at least one of: germanium telluride or antimony telluride.

11. A method, comprising:
electrically coupling, by a system comprising at least one processor, a common radio frequency (RF) port of an RF switch to one or more selectable RF ports, wherein the common RF port is electrically coupled to a conductor, and wherein the one or more selectable RF ports are connected to the conductor via a phase change alloy material junction between the selectable RF port and the conductor, the electrically coupling comprising:
determining which of the one or more selectable RF ports to electrically couple to the common port via the conductor;
for each selectable RF port determined to be one to electrically couple to the common RF port,
determining whether the phase change alloy material junction between the selectable RF port and the conductor is in a conductive state or a nonconductive state, and, in response to the phase change alloy material junction being determined to be in a nonconductive state, controlling a heating element corresponding to the selectable RF port to change the phase change alloy material junction to a conductive state that electrically couples the selectable RF port to the conductor; and
for each selectable RF port determined not to be one to electrically couple to the common RF port,
determining whether the phase change alloy material junction between the selectable RF port and the conductor is in a conductive state or a nonconductive state, and, in response to the phase change alloy material junction being in a conductive state, controlling a heating element corresponding to the selectable RF port to change the phase change alloy material junction to a nonconductive state that electrically decouples the selectable RF port from the conductor.

12. The method of claim 11, wherein the common RF port is an input port that obtains an input signal, and wherein the electrically coupling comprises determining at least one of the one or more selectable RF ports as at least one corresponding output port usable to obtain the input signal.

13. The method of claim 11, wherein the common RF port is an output port, and further comprising determining, by the system, a single selectable RF port of the one or more selectable RF ports to be an input port that obtains an input signal, and wherein the electrically coupling couples the single selectable RF port to the common RF port.

14. The method of claim 13, wherein the single selectable RF port is a first selectable RF port determined to be a first input port, wherein the input signal is a first input signal, and further comprising determining, by the system, a second selectable RF port, other than the first selectable RF port, to be a second input port that obtains a second input signal, and wherein the electrically coupling couples the second input port RF port to the common RF port and decouples the first input port from the common RF port.

15. The method of claim 11, wherein the controlling of the heating element comprises pulsing the heating element with a first voltage or a current pulse to change the phase change alloy material junction to the conductive state, or pulsing the heating element with a second voltage or current pulse to change the phase change alloy material junction to the nonconductive state.

16. A multiport switch, comprising:
a common radio frequency (RF) port;
conductive material coupled to the common RF port;
respective selectable RF ports;
respective phase change alloy junctions between the conductive material and the respective selectable RF ports; and
respective heating elements that are individually controllable to determine whether the respective phase change alloy junctions are in respective conductive states or in respective nonconductive states,
wherein a phase change alloy junction of the respective phase change alloy junctions, in a conductive state, electrically couples a selectable RF port of the respective selectable RF ports to the conductive material, and wherein the phase change alloy junction of the respective phase change alloy junctions, in a nonconductive state, electrically decouples the selectable RF port of the respective selectable RF ports from the conductive material.

17. The multiport switch of claim 16, wherein the common RF port and the respective selectable ports are symmetrically distributed around a centered ground portion of the RF switch.

18. The multiport switch of claim 16, wherein the common RF port comprises an input port for a signal.

19. The multiport switch of claim 16, wherein one selectable RF port of the respective selectable RF ports is electrically coupled to the conductive material to route a signal from the one selectable RF port to the common RF port.

20. The multiport switch of claim 16, further comprising a thermally conductive dielectric layer between the respective phase change alloy junctions and the respective heating elements.
